(19) United States
(12) Patent Application Publication
(10) Pub. No.: US 2008/0179173 A1
(43) Pub. Date: Jul. 31, 2008

(54) Keypad and keypad assembly

(75) Inventors: Sun-Tae Jung, Anyang-si (KR); Joo-Hoon Lee, Yongin-si (KR)

Correspondence Address: CHA & REITER, LLC, 210 ROUTE 4 EAST STE 103, PARAMUS, NJ, 07652, US

(73) Assignee: Samsung Electronics Co., LTD.

(21) Appl. No.: 11/999,668

(22) Filed: Dec. 6, 2007

(30) Foreign Application Priority Data
Jan. 31, 2007 (KR) 9983/2007

(51) Int. Cl. H01H 9/00; H03M 11/00

(52) U.S. Cl. 200/314; 341/34

(57) ABSTRACT

A keypad and a keypad assembly are disclosed. The keypad includes a light guide layer, inside which light travels and electronic paper which is illuminated by light irradiated from the light guide layer and expresses at least one symbol by reflection of the light.

### CLAIM OF PRIORITY

This application claims the benefit of the earlier filing date, under 35 U.S.C. §119(a), to that patent application filed in the Korean Intellectual Property Office on Jan. 31, 2007 and assigned Serial No. 2007-9983, the entire disclosure of which is hereby incorporated by reference.

### BACKGROUND OF THE INVENTION

1. Field of the Invention

The present invention relates to a keypad assembly for a portable device, and in particular, to a keypad assembly using a light guide layer and electronic paper.

2. Description of the Related Art

As various portable devices have been released to the market, easy portability has emerged as an important issue. Moreover, with the development of a digital convergence technique for converging a plurality of portable devices into one, various functions are integrated into a portable wireless terminal. For example, a number of portable wireless terminals having an MP3 player, a digital camera, and a game console integrated therein have been released to the market. When various devices are integrated into a portable wireless terminal, it is a difficult challenge to integrate unique input keys of each of the devices into a keypad assembly of the portable wireless terminal. The number of key tops of the keypad assembly is limited, while there are numerous symbols to be input, such as the Korean alphabets, the English letters, numeric digits, and special symbols. Although such a problem has been solved by expressing a plurality of symbols on each of the key tops or using software, this solution causes inconvenience to users due to low visibility.

To solve this problem, a keypad assembly using electronic paper has been disclosed.

In the disclosed keypad assembly, invented by and granted to Huinan J. Yu with U.S. Pat. No. 7,053,799 and titled “Keypad with Illumination Structure”, electronic paper is interposed between a transparent keypad having actuator buttons and a plurality of switches. The electronic paper is illuminated through the transparent keypad using a light emitting device disposed between a housing and the transparent keypad, thereby expressing symbol patterns on the electronic paper.

However, the conventional keypad assembly using the electronic paper has problems as follows.

First, the light emitting device is disposed between the housing and the transparent keypad, making it difficult to prevent leakage of light. In particular, when a print is made on the transparent keypad, the luminance of light that is incident to the electronic paper degrades greatly, causing low visibility.

Second, when a user presses the actuator button, a transformed portion of the electronic portion directly presses a corresponding switch, resulting in a poor sense of clicking.

Third, a large number of light emitting devices for uniformly and brightly illuminating the electronic paper increases power consumption and manufacturing cost.

### SUMMARY OF THE INVENTION

An aspect of the present invention is to address at least the above problems and/or disadvantages. Accordingly, an aspect of the present invention is to provide a keypad and a keypad assembly having an efficient illumination structure and improved visibility.

According to one aspect of the present invention, there is provided a keypad including a light guide layer, inside which light travels, and electronic paper which is illuminated by light irradiated from the light guide layer and expresses at least one symbol by reflection of the light.

According to another aspect of the present invention, there is provided a keypad assembly. The keypad assembly includes a light guide layer, inside which light travels, electronic paper which is illuminated by light irradiated from the light guide layer and expresses at least one symbol by reflection of the light, and a switch board which faces the keypad and has at least one switch.

### BRIEF DESCRIPTION OF THE DRAWINGS

The above and other features and advantages of exemplary embodiments of the present invention will be more apparent from the following detailed description taken in conjunction with the accompanying drawings, in which:

FIG. 1 is a perspective view of a keypad assembly according to an exemplary embodiment of the present invention;

FIG. 2 is a cross-sectional view of a portion of the keypad assembly illustrated in FIG. 1;

FIG. 3 is a view illustrating the function of light extracting patterns illustrated in FIG. 2;

FIG. 4 is a view illustrating another arrangement of light extracting patterns;

FIG. 5 is a partial cut view of electronic paper illustrated in FIG. 1;

FIGS. 6A and 6B are views showing examples in which a light coupling means is applied;

FIGS. 7A through 7C are views for explaining electronic paper using active matrix driving;

FIG. 8 illustrates a touch keypad according to a second exemplary embodiment of the present invention;

FIG. 9 illustrates a touch keypad according to a third exemplary embodiment of the present invention; and

FIG. 10 illustrates a touch keypad according to a fourth exemplary embodiment of the present invention.

Throughout the drawings, the same drawing reference numerals will be understood to refer to the same elements, features and structures.

### DETAILED DESCRIPTION OF THE INVENTION

The matters defined in the description such as a detailed construction and elements are provided to assist in a understanding of exemplary embodiments of the invention. Accordingly, those of ordinary skill in the art will recognize that various changes and modifications of the embodiments described herein can be made without departing from the scope and spirit of the invention. Also, descriptions of well-known functions and constructions are omitted for clarity and conciseness.

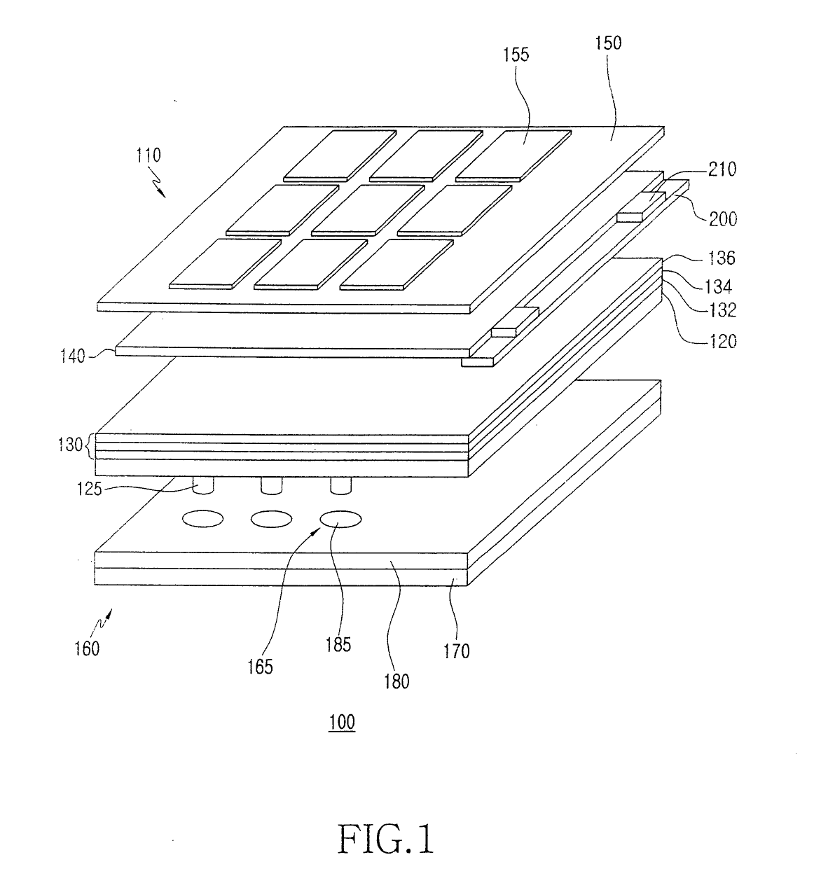

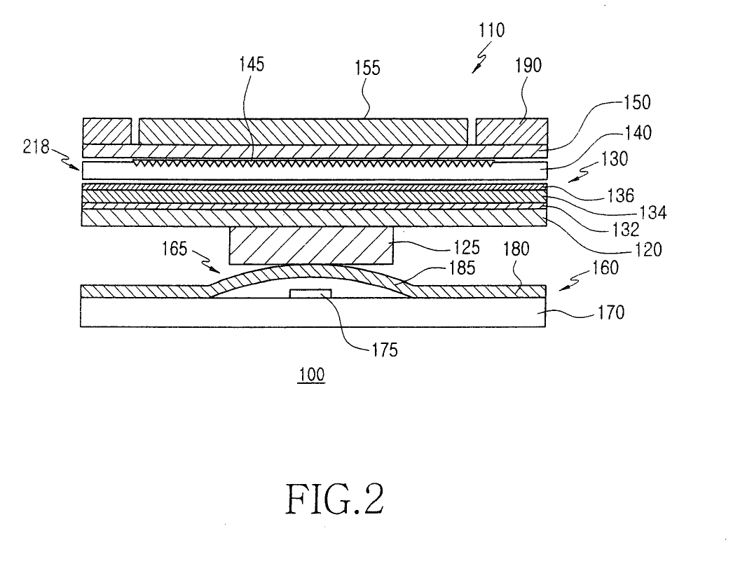

FIG. 1 is a perspective view of a keypad assembly 100 according to an exemplary embodiment of the present invention, and FIG. 2 is a cross-sectional view of a portion of the keypad assembly 100 illustrated in FIG. 1. The keypad assembly 100 can be mounted in a portable wireless terminal and includes a keypad 110 and a switch board 160 that are disposed to face each other, a second Printed Circuit Board (PCB) 200, and at least one light emitting device 210.

The keypad 110 includes an upper elastic layer 150, a light guide layer 140, electronic paper 130, and a lower elastic layer 120.

The upper elastic layer 150 may take various forms such as a square plate and includes a plurality of key tops 155 on its top surface. The upper elastic layer 150 has elasticity and thus the key top 155 returns to its original position after being pressed by a user. Thus, the upper elastic layer 150 returns to its original form after being deformed and returns the key top 155 to its original position after the operation of the key top 155 due to its self-restoring force. To prevent leakage of light, the top surface of the upper elastic layer 150 on which the key tops 155 are not disposed is covered with a housing 190 of the portable wireless terminal. Alternatively, to prevent leakage of light, a black print may be made on the top surface of the upper elastic layer 150 where the key tops 155 are not disposed. The upper elastic layer 150 is fixed while being spaced apart from the light guide layer 140 in order to maintain an air layer between the upper elastic layer 150 and the light guide layer 140. For example, the edge of the upper elastic layer 150 may be attached to the edge of the light guide layer 140 using an adhesive. By doing so, the adhesive prevents light from leaking out from the center portion of the light guide plate 140. The light travels through reflection in a boundary between the light guide layer 140 and an air layer. However, the light may leak out because of not satisfying a total reflection condition in a boundary between the light guide layer 140 and the adhesive. Since a part of the light, which remains after illuminating the electronic paper 130, reaches the edge of the light guide layer 140, it is desirable to attach the edge of the light guide player 140 to the edge of the upper elastic layer 150. If the center portion of the upper elastic layer 150 on which the key tops 155 are arranged is attached to the top surface of the light guide layer 140, then an air layer cannot be provided between the light guide layer 140 and the upper elastic layer 150. For this reason, it is preferable that the surface of the upper elastic layer 150 has a characteristic of not being attached to the top surface of the light guide layer 140. To this end, the bottom surface of the upper elastic layer 150 may be processed to be rough or may be coated with a releasing agent to have slipperiness. The upper elastic layer 150 may be formed of a high-transparent rubber material having low rigidity, high elastic strain, high elastic restoring force, and high light transmittance, and preferably, of polyurethane or silicone.

Unlike in the current exemplary embodiment of the present invention, if most portions of the upper elastic layer 150 closely contact or are attached to the top surface of the light guide layer 140, the refractive index of the upper elastic layer 150 or the adhesive may be lower than that of the light guide layer 140. In the same condition as the above, the light guide player 140 may closely contact or be attached to the top surface of the electronic paper 130.

The plurality of key tops 155 are arranged on the top surface of the upper elastic layer 150 and each of the key tops 155 may be attached to the top surface of the upper elastic layer 150 using an adhesive or may be formed as one piece with the upper elastic layer 150 using injection molding. Each of the key tops 155 may be formed of the same material as that of the upper elastic layer 150 or polycarbonate or acryl-group resin. Although each of the key tops 155 is a square block in shape in the current exemplary embodiment of the present invention, it may be in another shape like a circular pole or an oval pole. The key tops 155 may also be attached directly to the top surface of the light guide layer 140 without a need for the upper elastic layer 150.

Unlike in the current exemplary embodiment of the present invention, the upper elastic layer 150 may be substituted by a thin transparent film having no key top. In this case, a user input position may be specified on the top surface of the transparent film using a color or black/white print. For example, a lattice pattern, i.e., a pattern formed by horizontal straight lines and vertical straight lines that intersect each other perpendicularly, may be formed on the top surface of the transparent film. In this case, the top surface of the transparent film is divided into a displayed portion that has no black/white print thereon and a non-displayed portion that has a black/white print thereon. Alternatively, the user input position may be specified by the electronic paper 130. In this case, in order to implement more flexible display using the electronic paper 130, only an outline is printed on the top surface of the transparent film and most parts of the top surface of the transparent film except for the printed outline may be maintained transparent. Such a design is not applicable to a general keypad having no display function, but it may be effectively applied to a keypad having a display function like that suggested in the present invention.

Unlike in the current exemplary embodiment of the present invention, the upper elastic layer 150 may not be required by enabling the light guide layer 140 to function as the upper elastic layer 150. In this case, the key tops 155 may be attached directly to the top surface of the light guide player 140, a print for specifying a user input position may be formed on the top surface of the light guide layer 140 in order to remove a need for the key tops 155, or only an outline may be printed on the top surface of the light guide layer 140 without using the key tops 155. The light guide layer 140 enables the key top 150 to return to its original position after being pressed by a user. For example, the light guide layer 140 may be formed of a light guide film whose both surfaces are coated with a material having relatively low refractive index in order to guide light irrespective of a change in an external environment and its coated top surface may have a print thereon as mentioned above. The keypad structured as described above may have thickness significantly less than that of a conventional keypad.

The light guide layer 140 may have various shapes, e.g., a square plate. The light guide layer 140 is positioned such that its top surface faces the bottom surface of the upper elastic layer 150, and guides the light coupled to its inner side. The coupled light travels from a first side surface of the light guide layer 140 to a second side surface that is on the opposite side of the first side surface. The first side surface of the light guide layer 140 refers to a side surface to which the light incident from outside is coupled. The light coupled to the inner side of the light guide layer 140 travels to the inner side of the light guide layer 140 by total reflection in a boundary between the light guide layer 140 and an air layer outside the light guide layer 140. Because of its elasticity, the light guide layer 140 is restored to its original form after being deformed by the depression of the key top 155. The light guide layer 140 may be formed of a material having high elastic strain, high elastic restoring force, and high light transmittance, and preferably, of polycarbonate, polyurethane, silicone, or polymethylmethacrylate (PMMA).

The light guide layer 140 has a plurality of light extracting patterns 145 (see FIG. 2) which extract a portion of the light traveling into the light guide layer 140 towards the outside of the light guide layer 140 in order to cause the extracted portion of the light to be incident to the electronic paper 130. The light extracting patterns 145 are formed on the top surface of the light guide layer 140. The light extracting patterns 145 reflect the incident light towards the electronic paper 130. Each of the light extracting patterns 145 may be formed of at least one V-shape substances, i.e., grooves or prominences-and-depressions whose cross sections that are perpendicular to their longitudinal direction are shaped like V's or a plurality of grooves or prominences-and-depressions shaped like pyramids, on the top surface of the light guide layer 140. When each of the light extracting patterns 145 is implemented with the V-shape substances, the V-shape substances may extend from a first side surface of the light guide layer 140 to a second side surface that is on the opposite side of the first side surface. The V-shape substances may be sawtooth in shape or may be in a shape that is slightly deformed from the saw tooth shape according to an arbitrary design value.

If necessary, each of the light extracting patterns 145 may be formed of engraved grooves in various shapes or a plurality of embossed protrusions on the top surface of the light guide layer 140. For example, each of the light extracting patterns 145 may be formed of a plurality of grooves or a plurality of protrusions, each of which may be in various shapes such as a half circle or a triangular pyramid, or combination thereof. If necessary, each of the light extracting patterns 145 may be implemented as a reflection or scattering pattern formed by a scratch or a print.

As the light within the light guide layer 140 is attenuated while traveling from the first side surface that is adjacent to the light emitting device 210 towards the second side surface, luminance distribution on the keypad 110 may have a characteristic that luminance gradually decreases in a direction from the first side surface of the light guide layer 140 to a second side surface 218 of the light guide layer 140. To solve the luminance non-uniformity problem, the light extracting pattern 145 may be structured such that the density of the light extracting pattern 145 gradually increases in the direction from the first side surface of the light guide layer 140 to the second side surface 218 based on the same pattern size. The density of the light extracting pattern 145 may be changed by changing the number of the light extracting patterns 145 or the size of the light extracting pattern 145. The density of the light extracting pattern 145 may be defined as an area occupied by the light extracting pattern 145 per unit area. Alternatively, the light extracting pattern 145 may be structured such that the size of the light extracting pattern 145 increases in the direction from the first side surface of the light guide layer 140 to the second side surface 218. When the light extracting pattern 145 is implemented with the V-shape substance, the density of the light extracting pattern 145 may be defined as the peak interval of the V-shape substance. In this case, as the peak interval decreases, the density of the light extracting pattern 145 increases and thus the ratio of effective reflected light, which passes through the bottom surface of the light guide layer 140, to incident light increases. On the other hand, as the peak interval increases, the density decreases, and thus the ratio of effective reflected light to incident light decreases.

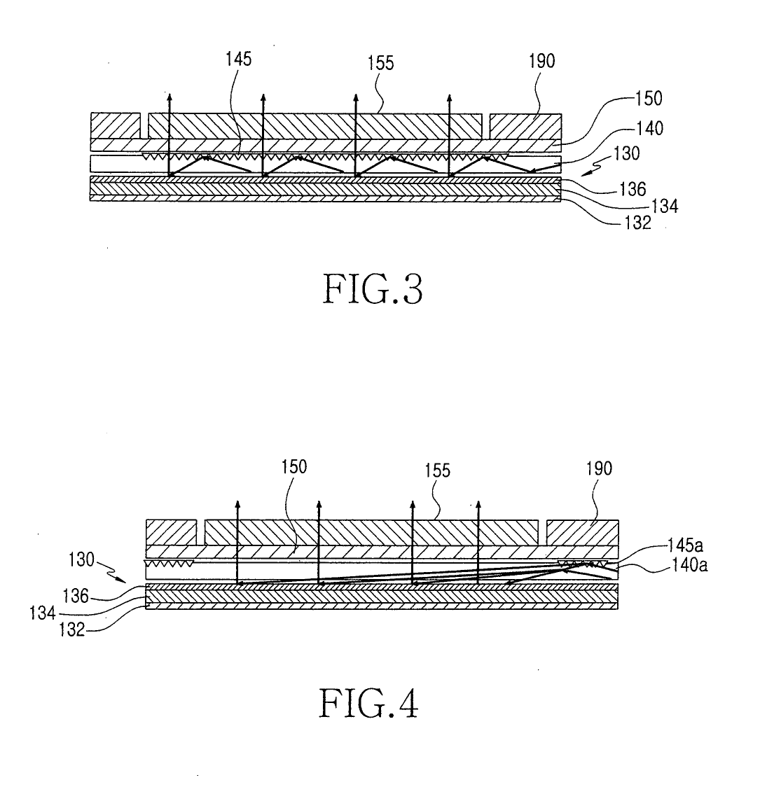

FIG. 3 is a view for explaining the function of the light extracting patterns 145 illustrated in FIG. 2. As illustrated in FIG. 3, each of the light extracting patterns 145 is disposed substantially perpendicular below its counterpart key top 155 in order to correspond to the key top 155. The light traveling in the light guide layer 140, through total reflection, is incident to the light extracting pattern 145, and most portions of the light reflected or scattered to the electronic paper 130 by the light extracting pattern 145 do not meet a total reflection condition in the inner side of the light guide layer 140. In this case, the light is irradiated toward the light guide layer 140 after passing through the bottom surface of the light guide layer 140. The irradiated light is reflected by the electronic paper 130 and then is irradiated outside the light guide layer 140 after passing through the light guide layer 140 and the upper elastic layer 150. Some portions of the light that travels without being reflected or scattered by the light extracting pattern 145 or some portions of the light that is reflected or scattered by the light extracting pattern 145 may continue traveling within the light guide layer 140 while satisfying the total reflection condition.

If necessary, each of the light extracting patterns 145 may be disposed around an outer circumference of its counterpart key top 155 in order to correspond to the key top 155.

FIG. 4 is a view for explaining another arrangement of light extracting patterns 145a. Each of the light extracting patterns 145a is disposed around an outer circumference of its counterpart key top 155 in order to correspond to the key top 155 and is implemented with a reflecting or scattering pattern. Light traveling in light guide layer 140a, by total reflection, is incident to the light extracting pattern 145a and reflected toward the counterpart key top 155. However, portions of light reflected or scattered to the electronic paper 130 by the light extracting pattern 145a does not satisfy a total reflection condition like when an incident angle is less than a critical angle, and thus the light is irradiated toward outside the light guide layer 140a after passing through the bottom surface of the light guide layer 140. The irradiated light is reflected by the electronic paper 130 and then is irradiated outside the light guide layer 140a after passing through the light guide layer 140a and the upper elastic layer 150. Some portions of the light that travels without being reflected or scattered by the light extracting pattern 145a or some portions of the light that is scattered-or reflected can continue traveling within the light guide layer 140a while satisfying the total reflection condition.

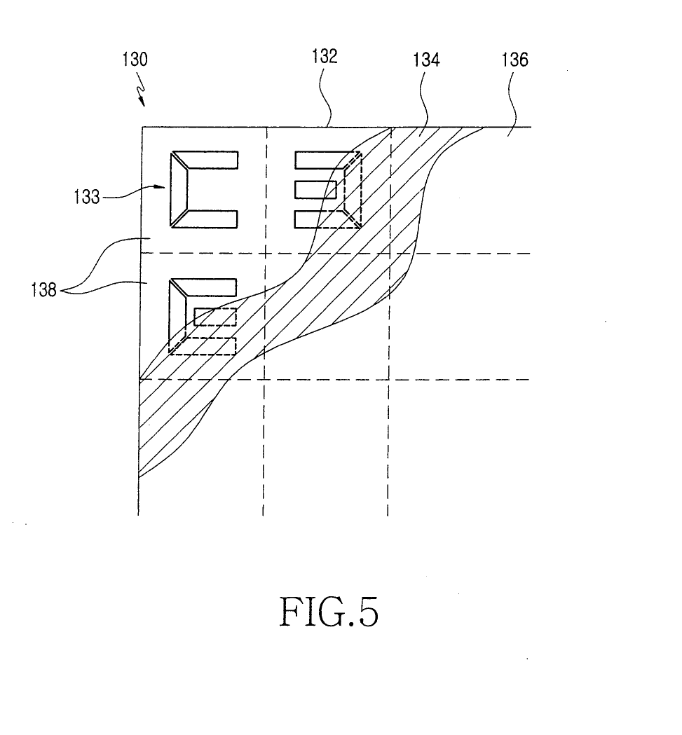

FIG. 5 is a partial cut view of the electronic paper 130 illustrated in FIG. 1.

The electronic paper 130 is disposed such that its top surface faces the bottom surface of the light guide layer 140. The electronic paper 130 is illuminated by the light irradiated from the light guide layer 140 and expresses a plurality of symbols by the reflection of the light. The symbols may include for example the Korean alphabets, the English letters, numeric digits, special symbols and icons, e.g., a clock-shape icon or a phone-shape icon. Each of the symbols expressed by the electronic paper 130 is shown through its counterpart key top 155. The electronic paper 130 includes a lower electrode layer 132, an ink layer 134, and an upper electrode layer 136 that is transparent to visible light, which are deposited sequentially. The electronic paper 130 includes a plurality of display regions 138 that correspond to the key tops 155 based on one-to-one correspondence and each of the display regions 138 displays at least one symbol such as ‘L’ and ‘C’. To display the symbols, the upper electrode layer 132 has a plurality of electrode patterns 133 that correspond to the display regions 138 based on one-to-one correspondence and each of the electrode patterns 133 includes a plurality of segments. Each of the electrode patterns 133 has the same shape as that of the symbol to be displayed by the electrode pattern 133. A voltage is applied to each of the segments of the electrode pattern 133. An electrode pattern 133 shaped like ‘C’ as illustrated in FIG. 5 is composed of three segments and expresses the symbols ‘C’ or ‘L’ by segment-based voltage supply. In one aspect, each of the electrode patterns 133 may be composed of a single pigment. When a voltage is applied to the lower electrode layer 132, the ink layer 134 expresses a color or black/white symbol by movement of particles according to an applied electric field, i.e., an electrophoretic phenomenon. For example, electro-phoretic electronic paper by E-Ink Corporation expresses a black/white pattern by disposing microcapsules filled with transparent fluid containing white and black particles between an upper electrode and a lower electrode and applying an electric field to each of the microcapsules. The white particle is charged with positive (+) electricity and the black particle is charged with negative (−) electricity, and thus they move in opposite directions according to the applied electric field. The electronic paper 130 according to the present invention can express a black/white symbol or a color symbol by depositing a color filter on the ink layer 134, using color particles for the ink layer 134 instead of black/white particles, or using a Light Emitting Diode (LED) or a Red/Green/Blue (RGB) LED for the light emitting device 210. The upper electrode layer 136 may function as a ground. The lower electrode layer 132 may be a Flexible Printed Circuit Board (FPCB).

The lower elastic layer 120 (returning to FIG. 2) is disposed such that its top surface faces the bottom surface of the electronic paper 130, and closely contacts or is attached to the bottom surface of the electronic paper 130 and has a similar shape to that of the electronic paper 130 on the whole. The lower elastic layer 120 has elasticity, supports the electronic paper 130, and enables the electronic paper 130 to be restored to its original form after being deformed. The elasticity of the lower elastic layer 120 is a self-restoring force and thus can be restored to its original form after being deformed. The lower elastic layer 120 may be formed of the same or different material as that of the upper elastic layer 150.

A plurality of protrusions 125 (FIG. 2) are disposed on the bottom surface of the lower elastic layer 120. The protrusions 125 may be formed of a material the same as or different from that of the lower elastic layer 120, or may be formed of polycarbonate or acryl-group resin and then attached to the bottom surface of the lower elastic layer 120. Each of the protrusions 125 may be in an arbitrary shape such as a truncated cone or a trapezoid hexahedron or combination thereof. Each of the protrusions 125 is disposed perpendicularly below its counterpart key top 155 in order to correspond to the key top 155. The size and shape of each of the protrusions 125 may be set based on the size of a dome 185 included in the switch board 160. For example, when the dome 185 is a half circle having a width or radius of 5 mm, the protrusion 125 may have a width of 2 mm and a thickness of 0.2-0.3 mm.

The switch board 160 (see FIG. 2) includes a first PCB 170 and a dome sheet 180.

The first PCB 170 includes a plurality of conductive contact members 175 on its top surface and each of the conductive contact members 175 constitutes a switch 165 with its counterpart dome 185. The switch 165 is disposed perpendicularly below its counterpart key top 155 in order to correspond to the key top 155.

The dome sheet 180 is attached to the top surface of the first PCB 170 and includes a plurality of conductive domes 185 shaped like half circles. Each of the conductive domes 185 completely covers its counterpart contact member 175.

Once the user presses one of the key tops 155, a portion of the keypad 110 under the pressed key top 155 is deformed towards the switch board 160 and thus the counterpart protrusion 125 included in the deformed portion presses the counterpart dome 185. The pressed dome 185 then electrically contacts the corresponding contact member 175, resulting in a switch “ON” condition. When the protrusion 125 is formed of rubber, the surface of the protrusion 125 is sticky and thus the dome 185 is likely to be attached to the protrusion 125. Thus, the surface of the dome 185 may be processed to be rough or may be coated with a releasing agent to have slipperiness. Unlike in the current exemplary embodiment of the present invention, the protrusion 125 may be attached onto the dome 185 instead of being formed in the lower elastic layer 120.

The second PCB 200 (see FIG. 1) is attached to an edge portion of the bottom surface of the light guide layer 140. The at least one light emitting device 210 is mounted on the top surface of the second PCB 200 in such a way that the first side surface of the light guide layer 140 faces the light emitting surface of the light emitting device 210. The light irradiated from the light emitting device 210 is coupled into the light guide layer 140 through the first side surface of the light guide layer 140. The second PCB 200 may be a general FPCB and the light emitting device 210 may be a general LED.

In one aspect, an edge portion of one side of the light guide layer 140 may extend up to the top surface of the first PCB 170 in the shape of a wedge without a need for the second PCB 200. In this case, the light emitting device 210 is mounted on the top surface of the first PCB 170.

Alternatively, an edge portion of one side of the light guide layer 140 may be bent in order to extend up to the top surface of the first PCB 170 without a need for the second PCB 200. In this case, the light emitting device 210 is mounted on the top surface of the first PCB 170.

The keypad assembly 100 as illustrated in FIG. 1 may further include a light coupling means for improving light coupling efficiency by being disposed in a light traveling path between the light emitting device 210 and the light guide layer 140.

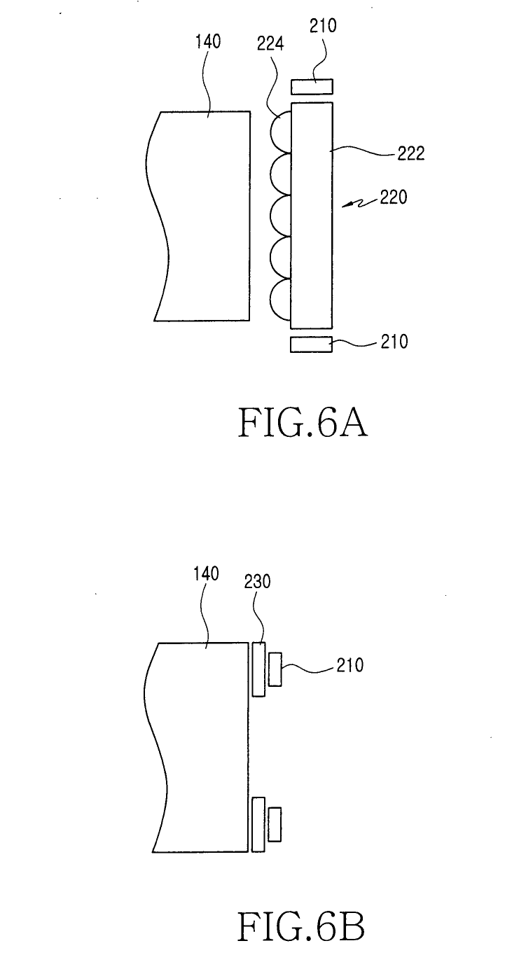

FIGS. 6A and 6B are views showing examples in which a light coupling means is applied. Referring to FIG. 6A, a lens bar 220 is provided as the light coupling means. The lens bar 220 includes a substrate 222 which has a front surface that faces the first side surface of the light guide layer 140 and may be in various shapes such as a square flat plate and a plurality of micro lenses 224 convexly protruding from the front surface of the substrate 222. The plurality of micro lenses 224 have the same size, shape, and angle of view as one another, and the lens bar 220 may be manufactured by performing injecting molding on glass or attaching a plurality of micro lenses onto a glass flat plate. The convex lens surface of each of the micro lenses 224 may be spherical or non-spherical. The light emitting device 210 is disposed such that its light emitting surface faces both side surfaces of the substrate 222 and light emitted from the light emitting device 210 is coupled into the substrate 222 through a counterpart side surface of the substrate 222. The light coupled into the substrate 222 is irradiated outside the substrate 222 through the micro lenses 224 and the light irradiated outside the lens bar 220 is coupled into the light guide layer 140 through the first side surface of the light guide layer 140.

Referring to FIG. 6B, lenses 230 are provided as the light coupling means. Each of the lenses 230 is interposed between the light emitting surface of the light emitting device 210 and the first side surface of the light guide layer 140 and couples light incident from the light emitting device 210 into the light guide layer 140 through the first side surface of the light guide layer 140.

Although the electronic paper 130 using segment driving has been described so far, the keypad assembly 100 as illustrated in FIG. 1 may include electronic paper using active matrix driving instead of the electronic paper 130.

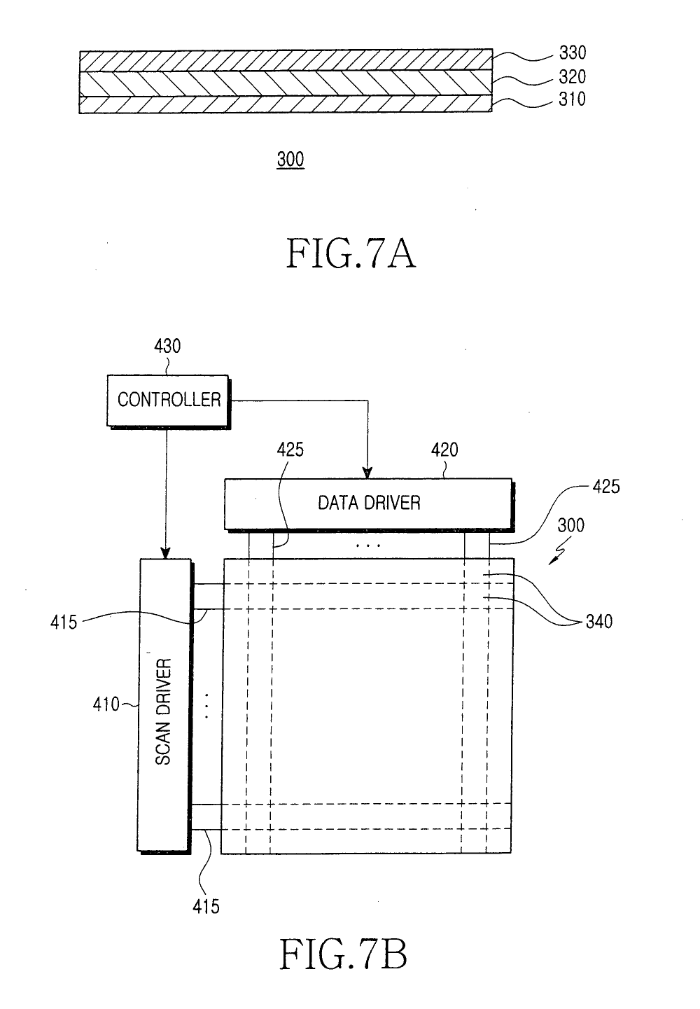

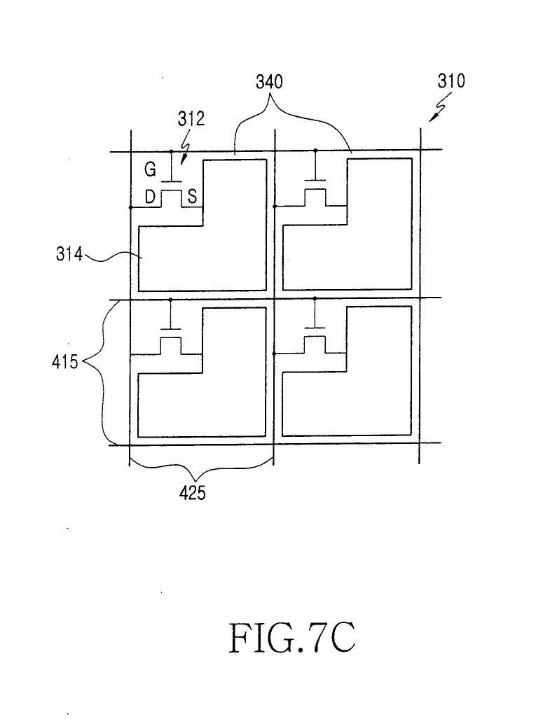

FIGS. 7A through 7C are views for explaining electronic paper 300 using active matrix driving. FIG. 7A is a cross-sectional view of the electronic paper 300, FIG. 7B illustrates a driving device for the electronic paper 300, and FIG. 7C is a circuit diagram of a lower electrode layer. The electronic paper 300 includes a lower electrode layer 310, an ink layer 320, and an upper electrode layer 330 having transparency to visible light, which are deposited sequentially. The electronic paper 300 includes a plurality of pixels 340, each of which expresses a single dot. Using combinations of the dots, an arbitrary symbol can be expressed. Each symbol expressed by the electronic paper 300 is shown through a counterpart key top. To this end, the lower electrode layer 310 has a plurality of pixel electrodes 314 that correspond to the pixels 340 based on one-to-one correspondence and each of the pixel electrodes 314 is connected to a counterpart scan line 415 and a counterpart data line 425 through a counterpart Thin Film Transistor (TFT) 312. Each TFT 312 has a gate G connected to the scan line 415, a drain D connected to the data line 425, and a source S connected to the pixel electrode 314. A scan driver 410 sequentially provides address signals to the scan lines 415 under the control of a controller 430 and a data driver 420 provides data signals to the data lines 425 under the control of the controller 430. Each TFT 312 functions as an on/off switch, and is turned on when signals are provided to both the scan line 415 and the data line 425 connected to the TFT 312. When the TFT 312 is turned on, a voltage is applied to the counterpart pixel electrode 314. The ink layer 320 expresses a color or black/white symbol by movement of particles according to an applied electric field. The upper electrode layer 330 functions as a ground.

Although user input is sensed by press-type switch driving in the first exemplary embodiment of the present invention, touch keypads using touch sensors will be used as examples in the exemplary embodiments to be described below. Each of the touch keypads includes the light guide layer 140 and the electronic paper 130 illustrated in FIG. 1 and thus a description thereof will not be provided. It should also be recognized that each of the touch keypads may include the electronic paper 300 illustrated in FIG. 7A.

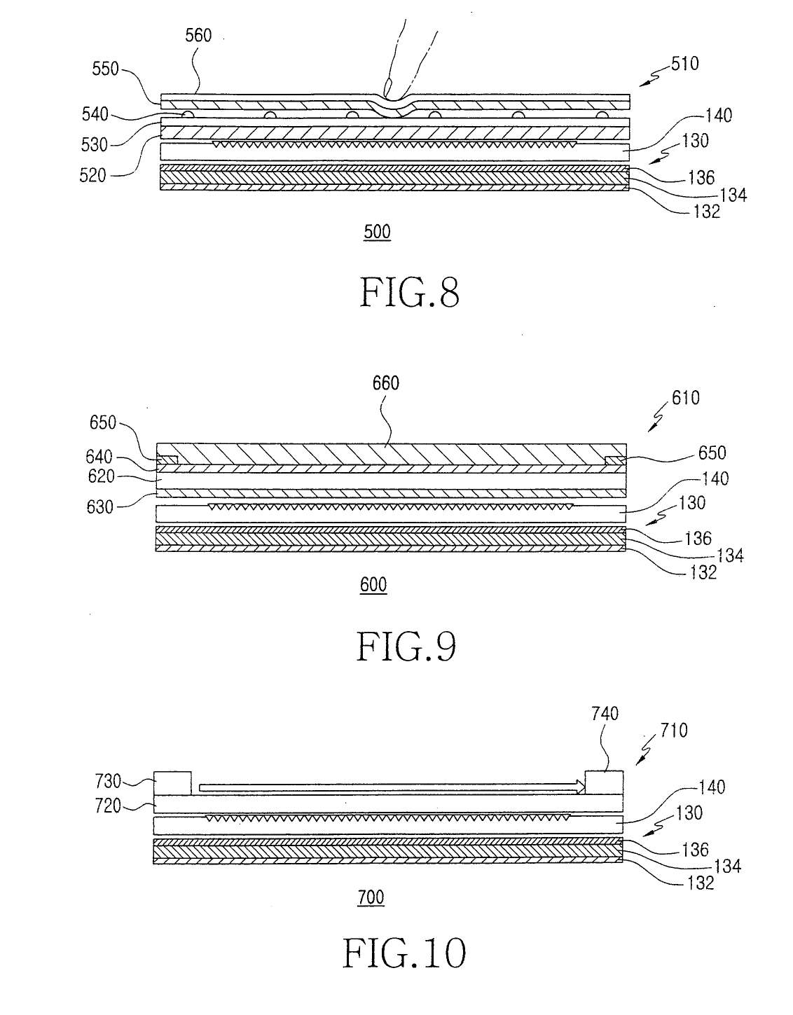

FIG. 8 illustrates a cross-sectional view of touch keypad 500 according to the second exemplary embodiment of the present invention. The keypad 500 is a touch keypad of a resistance-sensing type and includes the light guide layer 140 and the electronic paper 130 illustrated in FIG. 1 and a touch sensor 510.

The touch sensor 510 may have various shapes such as a square plate. The touch sensor 510 is disposed such that its bottom surface faces the top surface of the light guide layer 140, and is transparent to visible light on the whole. The touch sensor 510 includes a substrate 520, a lower conductive layer 530, a plurality of spacers 540, an upper conductive layer 550, and a protection layer 560, which are deposited sequentially. The substrate 520 is disposed such that its bottom surface faces the top surface of the light guide layer 140, and may be formed of glass or acryl. The lower conductive layer 530 is deposited on the substrate 520. The plurality of spacers 540 are disposed on the lower conductive layer 530 in order to perform an insulation function by being interposed between the lower conductive layer 530 and the upper conductive layer 550. The plurality of spacers 540 is disposed at the same interval uniformly on the top surface of the lower conductive layer 530. The upper conductive layer 550 is deposited on the lower conductive layer 530. Each of the lower conductive layer 530 and the upper conductive layer 550 may be formed of Indium-Tin Oxide (ITO). The protection layer 560 is deposited on the upper conductive layer 550 for preventing the upper conductive layer 550 from being damaged by contact of a user input means such as a user's finger or a touch pen. The protection layer 560 may be formed of polyethylene terephthalate (PET). When the user presses one spot of the top surface of the touch sensor 500, a corresponding portion of the upper conductive layer 550 is deformed towards the lower conductive layer 530 and thus the deformed portion electrically contacts the lower conductive layer 530. A particular voltage is applied between the lower conductive layer 530 and the upper conductive layer 550 and an electrical potential difference is generated in a contact position between the lower conductive layer 530 and the upper conductive layer 550. Thus, the user input position can be recognized by sensing a position where the electrical potential difference is generated.

FIG. 9 illustrates a cross-sectional view of a touch keypad 600 according to the third exemplary embodiment of the present invention. The keypad 600 is a touch keypad of an electrostatic capacity sensing type and includes the light guide layer 140 and the electronic paper 130 illustrated in FIG. 1 and a touch sensor 610.

The touch sensor 610 may have various shapes such as a square plate. The touch sensor 610 is disposed such that its bottom surface faces the top surface of the light guide layer 140, and is transparent to visible light on the whole. The touch sensor 610 includes a lower conductive layer 630, a substrate 620, an upper conductive layer 640, a plurality of electrodes 650, and an insulating layer 660, which are deposited sequentially. The substrate 620 is disposed such that its bottom surface faces the top surface of the light guide layer 140, and the upper conductive layer 640 and the lower conductive layer 630 are deposited on the top surface and the bottom surface of the substrate 620, respectively. Each of the lower conductive layer 630 and the upper conductive layer 640 may be formed of Indium-Tin Oxide (ITO). The plurality of electrodes 650 are disposed on the edge of the upper conductive layer 640, and preferably, at four corners of the upper conductive layer 640. An Alternating Current (AC) voltage is applied to the electrodes 650, thereby causing the current to flow in the entire upper conductive layer 640. The insulating layer 660 is deposited on the upper conductive layer 640. When a user input means contacts one spot of the top surface of the touch sensor 610, the flow of current changes from the contact position. Thus, the user input position can be recognized by sensing a position where the flow of current changes.

FIG. 10 illustrates a cross-sectional view of a touch keypad 700 according to the fourth exemplary embodiment of the present invention. The keypad 700 is a touch keypad of an infrared light sensing type and includes the light guide layer 140 and the electronic paper 130 illustrated in FIG. 1 and a touch sensor 710.

The touch sensor 710 may have various shapes such as a square plate on the whole. The touch sensor 710 is disposed such that its bottom surface faces the top surface of the light guide layer 140, and is transparent to visible light on the whole. The touch sensor 710 includes a substrate 720, and a plurality of infrared light generators 730 and a plurality of infrared light detectors 740 on the top surface of the substrate 720. The substrate 720 is disposed such that its bottom surface faces the top surface of the light guide layer 140, and the infrared light generators 730 and the infrared light detectors 740 are mounted on the top surface of the substrate 720. The substrate 720 may be a transparent PCB, the infrared light generators 730 may be infrared light emitting diodes, and the infrared light detectors 740 may be phototransistors. The infrared light generators 730 are disposed in order to form an infrared light grid over the entire top surface of the substrate 720. For example, the infrared light generators 730 are disposed at the same interval as one another in a left end and an upper end of the substrate 720, the infrared light detectors 740 are disposed at the same interval as one another in a right end and a lower end of the substrate 720, and the infrared light generators 730 may correspond to the infrared light detectors 740 based on one-to-one correspondence. When a user input means is positioned in a particular spot that is adjacent to the top surface of the touch sensor 700, it blocks corresponding infrared light and the output of the corresponding infrared light detector 740 is extinguished. Thus, the user input position can be recognized by sensing a position where the output of the infrared light detector 740 changes.

While the keypad and the keypad assembly according to the invention has been shown and described with reference to exemplary embodiments thereof, it will be understood by those skilled in the art that various changes in form and details may be made therein without departing from the spirit and scope of the invention.

For example, the touch keypads of a resistance-sensing type, an electrostatic capacity sensing type, and an infrared light sensing type have been used as examples in the exemplary embodiments of the present invention described, a combination structure of the light guide layer and the electronic paper suggested in the present invention may also be applied to a touch keypad of a ultrasonic sensing type, which is structured in a manner similar to the touch keypad of the fourth exemplary embodiment of the present invention, a touch keypad of a ferroelectric type using crystal oscillators, a touch keypad of a tension sensing type using tension sensors, and a touch keypad of an electromagnetic field sensing type using a touch pen generating an electromagnetic field signal and electromagnetic sensors.

As described above, according to the present invention, by illuminating electronic paper using a light guide layer, the leakage of light can be prevented and visibility can be improved. Moreover, light irradiated from the light guide layer is incident directly to the electronic paper, thereby achieving efficient illumination. Furthermore, a sense of clicking can also be improved by a protrusion for a clicking operation. In addition, the number of required light emitting devices, power consumption, and manufacturing cost can be reduced by including the light guide layer.

What is claimed is:

1. A keypad comprising:
a light guide layer, inside which light travels, said light guide layer including a light extracting pattern; and
electronic paper which is illuminated by light irradiated from the light guide layer and expresses at least one symbol by reflection of the light.

2. The keypad of claim 1, wherein the electronic paper comprises:
an upper electrode layer;
a lower electrode layer including at least one electrode pattern; and
an ink layer which is interposed between the upper electrode layer and the lower electrode layer and expresses a symbol according to an applied electric field.

3. The keypad of claim 1, wherein the electronic paper expresses a symbol by combination of pixels and comprises:
an upper electrode layer;
a lower electrode layer comprising:
scan lines for inputting address signals;
data lines for inputting data signals;
a plurality of pixel electrodes corresponding to the pixels based on one-to-one correspondence; and
a plurality of Thin Film Transistors (TFTs) for connecting each of the pixel electrodes to the counterpart scan line and the counterpart data line; and
an ink layer which is interposed between the upper electrode layer and the lower electrode layer and expresses a symbol according to an applied electric field.

4. The keypad of claim 1, wherein said light extracting pattern causes the extracted portion of the light to be incident to the electronic paper.

5. The keypad of claim 1, further comprising at least one key top disposed on the light guide layer.

6. The keypad of claim 5, further comprising an upper elastic layer which has the key top on its top surface and restores the key top to its original position after the operation of the key top.

7. The keypad of claim 5, further comprising at least one protrusion disposed under the light guide layer and corresponding to the key top.

8. The keypad of claim 7, further comprising a lower elastic layer which has the protrusion on its bottom surface and restores the protrusion to its original position after the operation of the protrusion.

9. The keypad of claim 1, further comprising a touch sensor which is disposed such that its bottom surface faces the top surface of the light guide layer, and senses a user input position.

10. A keypad assembly comprising:
a light guide layer, inside which light travels, said light guide layer including a light extracting pattern;
electronic paper which is illuminated by light irradiated from the light guide layer and expresses at least one symbol by reflection of the light; and
a switch board disposed under the electronic paper and having at least one switch.

11. The keypad assembly of claim 10, wherein the electronic paper comprises:
an upper electrode layer;
a lower electrode layer including at least one electrode pattern; and
an ink layer which is interposed between the upper electrode layer and the lower electrode layer and expresses a symbol according to an applied electric field.

12. The keypad assembly of claim 10, wherein the electronic paper expresses a symbol by combination of pixels and comprises:
an upper electrode layer;
a lower electrode layer comprising:
scan lines for inputting address signals;
data lines for inputting data signals;
a plurality of pixel electrodes corresponding to the pixels based on one-to-one correspondence; and
a plurality of Thin Film Transistors (TFTs) for connecting each of the pixel electrodes to the counterpart scan line and the counterpart data line; and
an ink layer which is interposed between the upper electrode layer and the lower electrode layer and expresses a symbol according to an applied electric field.

13. The keypad assembly of claim 10, wherein the light extracting pattern causes the extracted portion of the light to be incident to the electronic paper.

14. The keypad assembly of claim 10, further comprising at least one key top disposed on the light guide layer.

15. The keypad assembly of claim 14, further comprising an upper elastic layer which has the key top on its top surface and restores the key top to its original position after the operation of the key top.

16. The keypad assembly of claim 14, further comprising at least one protrusion disposed under the light guide layer and corresponding to the key top.

17. The keypad assembly of claim 16, further comprising a lower elastic layer which has the protrusion on its bottom surface and restores the protrusion to its original position after the operation of the protrusion.

18. The keypad assembly of claim 10, further comprising at least one light emitting device for coupling light into the light guide layer.

19. The keypad assembly of claim 18, further comprising a light coupling means disposed in a light traveling path between the light emitting device and the light guide layer.

20. The keypad of claim 1, wherein the density of the light extracting pattern gradually increases in the traveling direction of said light.

21. The keypad assembly of claim 10, wherein the density of the light extracting pattern gradually increases in the traveling direction of said light.
